(19) United States
(12) Patent Application Publication
(10) Pub. No.: US 2024/0341122 A1
(43) Pub. Date: Oct. 10, 2024

(54) DISPLAY DEVICE AND METHOD FOR MANUFACTURING THE SAME

(71) Applicant: Samsung Display Co., Ltd., Yongin-Si (KR)

(72) Inventors: Se Hyun LEE, Yongin-si (KR); Won Jun LEE, Yongin-si (KR); Jin Joo HA, Yongin-si (KR)

(21) Appl. No.: 18/507,099

(22) Filed: Nov. 13, 2023

(30) Foreign Application Priority Data
Apr. 5, 2023 (KR) 10-2023-0044830

(51) Int. Cl. H10K 59/122; H10K 50/11; H10K 50/818

(52) U.S. Cl. CPC H10K 59/122; H10K 50/11; H10K 50/818; H10K 59/38

(57) ABSTRACT

A display device according to an embodiment includes a first electrode disposed at least in an emission area, a bank disposed around the emission area to surround the emission area and including a groove formed in an upper surface thereof, a light emitting stack disposed on the first electrode surrounded by the bank and including a light emitting layer and a first intermediate layer overlapping the light emitting layer, a second electrode disposed on the light emitting stack, and a reflective layer disposed on at least a portion of the bank to cover the groove.

### CROSS-REFERENCE TO RELATED APPLICATION

This application claims priority to Korean Patent Application No. 10-2023-0044830 filed on Apr. 5, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and a method for manufacturing the same.

### 2. Description of the Related Art

The importance of display devices has gradually increased with the development of multimedia. Accordingly, various display devices such as liquid crystal display devices and organic light emitting display devices have been developed.

### SUMMARY

Aspects of the present disclosure provide a display device with improved luminous efficiency and a method for manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device includes a first electrode disposed an emission area, a bank disposed around the emission area to surround the emission area and including a groove formed in an upper surface thereof, a light emitting stack disposed on the first electrode surrounded by the bank and including a light emitting layer and a first intermediate layer overlapping the light emitting layer, a second electrode disposed on the light emitting stack, and a reflective layer disposed on at least a portion of the bank to cover the groove.

In an embodiment, the first intermediate layer may include a first electron transport layer having a greater thickness or height in an edge area adjacent to the bank than in the other areas.

In an embodiment, the first electron transport layer may include ZnO.

In an embodiment, the first intermediate layer may further include a second electron transport layer disposed between the light emitting layer and the first electron transport layer.

In an embodiment, the first intermediate layer may be disposed between the light emitting layer and the second electrode, and the light emitting stack may further include a second intermediate layer disposed between the first electrode and the light emitting layer.

In an embodiment, the reflective layer may completely surround the emission area in a plan view.

In an embodiment, the display device may include emission areas which include the emission area and are spaced apart from each other. The bank may be disposed between adjacent emission areas to surround each of the emission areas, and may include at least one V-shaped or U-shaped groove disposed between the adjacent emission areas.

In an embodiment, the reflective layer may have a curved surface or an inclined surface corresponding to the groove of the bank.

In an embodiment, the reflective layer may include a mesh-shaped pattern layer including openings corresponding to the emission areas and may surround each of the emission areas.

In an embodiment, the reflective layer may include reflective patterns which are separated from each other and surround the emission areas, respectively.

In an embodiment, the first electrode may include a reflective electrode layer, the second electrode may include a transparent electrode layer, and light emitted from the light emitting layer may be transmitted through the second electrode and may be emitted in an upward direction of the light emitting layer.

In an embodiment, the display device may further include a light blocking layer or at least two color filters disposed on the reflective layer to overlap the reflective layer.

According to an aspect of the present disclosure, a display device includes a first electrode disposed in an emission area and including a reflective electrode layer, a bank disposed around the emission area to surround the emission area and including a groove formed in an upper surface thereof, a light emitting stack disposed on the first electrode, surrounded by the bank, and including a light emitting layer and at least one intermediate layer overlapping the light emitting layer, a second electrode disposed on the light emitting stack and including a transparent electrode layer, and a reflective layer disposed on at least a portion of the bank to cover the groove.

In an embodiment, the light emitting layer may be a quantum dot light emitting layer including quantum dots.

In an embodiment, the at least one intermediate layer may include an electron transport layer including ZnO.

In an embodiment, the electron transport layer may have a greater thickness or height in an area adjacent to the bank than in the other areas.

In an embodiment, the groove of the bank may completely surround the emission area in a plan view and may include at least one V-shaped or U-shaped groove in cross section.

In an embodiment, the reflective layer may completely surround the emission area in a plan view and may have a curved surface or an inclined surface corresponding to the groove of the bank.

According to an aspect of the present disclosure, a method for manufacturing a display device includes forming a first electrode on a substrate, forming a bank on the first electrode to surround the first electrode to define an emission area, the bank including a groove in an upper surface, forming a reflective layer on at least a portion of the bank to cover the groove, forming a light emitting stack on the first electrode in the emission area surrounded by the bank, the light emitting stack including a light emitting layer and at least one intermediate layer, irradiating ultraviolet (UV) light from below the substrate toward the reflective layer, and forming a second electrode on the light emitting stack.

In an embodiment, the light emitting stack may be formed by an inkjet printing process.

A display device according to embodiments may include a bank surrounding emission areas of pixels and including grooves in an upper surface thereof, and a reflective layer disposed on the grooves of the bank. Light loss of the pixels is reduced or minimized by the reflective layer such that luminous efficiency of the pixels and the display device including the pixels may be increased.

A method for manufacturing a display device according to embodiments may include forming a groove in an upper surface of a bank partitioning an emission area, forming a reflective layer on at least a portion of the bank to cover the groove, forming a light emitting stack in the emission area surrounded by the bank, and irradiating ultraviolet (UV) light from below a substrate to the reflective layer. At least some of the UV light irradiated to the reflective layer may be reflected by the reflective layer and be incident on the light emitting stack, and may change characteristics of the light emitting stack. Accordingly, luminous efficiency of a light emitting element and the pixel including the light emitting element may be increased, and light emitting quality of the light emitting element and the pixel including the light emitting element may be improved.

According to embodiments, a display device with improved luminous efficiency and a method for manufacturing the same may be provided.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to an embodiment;

FIG. 2 is a plan view illustrating a display area of the display device according to an embodiment;

FIG. 3 is a plan view illustrating a display area of the display device according to an embodiment;

FIG. 4 is a cross-sectional view illustrating the display device according to an embodiment;

FIG. 5 is a cross-sectional view illustrating a light emitting element according to an embodiment;

FIG. 6 is a cross-sectional view illustrating a display device according to an embodiment;

FIG. 7 is a cross-sectional view illustrating a display device according to an embodiment;

FIG. 8 is a cross-sectional view illustrating a display device according to an embodiment;

FIG. 9 is a cross-sectional view illustrating a display device according to an embodiment;

FIGS. 10, 11, 12, 13, 14 and 15 are cross-sectional views illustrating a method for manufacturing a display device according to an embodiment; and

FIG. 16 is a plan view illustrating a change in light emitting characteristics of a pixel according to an embodiment.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will filly convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

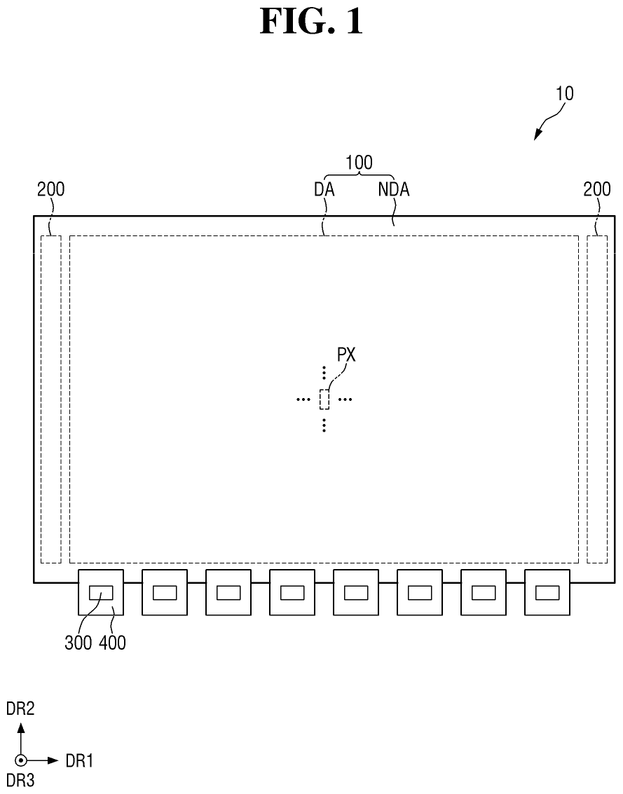

FIG. 1 is a plan view illustrating a display device 10 according to an embodiment.

Referring to FIG. 1, a display device 10 is a device that displays an image, and may be applied to various electronic devices such as televisions, laptop computers, monitors, billboards, and Internet of Things (IoT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). The display device 10 may also be applied to other electronic devices.

In an embodiment, the display device 10 may be a light emitting display device such as an organic light emitting display device using organic light emitting diodes, a quantum dot light emitting display device including a quantum dot light emitting layer, an inorganic light emitting display device including an inorganic semiconductor, and a micro light emitting display device using micro or nano light emitting diodes (micro LEDs or nano LEDs). Hereinafter, embodiments in which the display device 10 is a quantum dot light emitting display device have been described, but a type of the display device 10 is not limited thereto.

The display device 10 may include a display panel 100 including at least pixels PX, and first driving units 200 and second driving units 300 supplying driving signals to the pixels PX. The display device 10 may further include additional components. For example, the display device 10 may further include a power supply unit for supplying source voltages to the pixels PX, the first driving units 200, and the second driving units 300, a timing controller for controlling operations of the first driving units 200 and the second driving units 300, and the like.

The display panel 100 may include a display area DA and a non-display area NDA (also referred to as a “bezel area”). The display area DA may be an area displaying an image by using the pixels PX. The non-display area NDA is an area other than the display area DA, and an image may not be displayed in the non-display area NDA. In an embodiment, the non-display area NDA may be positioned around the display area DA, and may surround the display area DA.

In an embodiment, the display panel 100 may have a rectangular shape in a plan view. For example, the display panel 100 may include two first sides extending in a first direction DR1 and two second sides extending in a second direction DR2 crossing the first direction DR1. A corner where the first side and the second side of the display panel 100 meet may be right-angled, but is not limited thereto, and may also be curved. In an embodiment, the first side may be longer than the second side, but is not limited thereto.

In FIG. 1, the first direction DR1, the second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. In an embodiment, the first direction DR1 may refer to a transverse direction in FIG. 1, and the second direction DR2 may refer to a longitudinal direction in FIG. 1. The third direction DR3 may refer to an upward direction (or a thickness or height direction of the display panel 100) in FIG. 1.

The shape of the display panel 100 in a plan view is not limited to the illustrated shape, and may also be a circular shape or other shapes. In addition, it has been illustrated in FIG. 1 that the display panel 100 has a flat shape, but embodiments are not limited thereto. For example, the display panel 100 may include a curved portion curved with a predetermined curvature. The display panel 100 may be rigid or flexible.

At least one surface of the display panel 100 may be a display surface on which an image is displayed. For example, the display panel 100 may display an image on any one surface (e.g., an upper surface) or display an image on at least two surfaces (e.g., an upper surface and a lower surface, or an upper surface and at least one side surface).

The pixels PX may emit light with luminance corresponding to respective driving signals supplied from the first driving units 200, the second driving units 300, and the like. Accordingly, an image may be displayed in the display area DA.

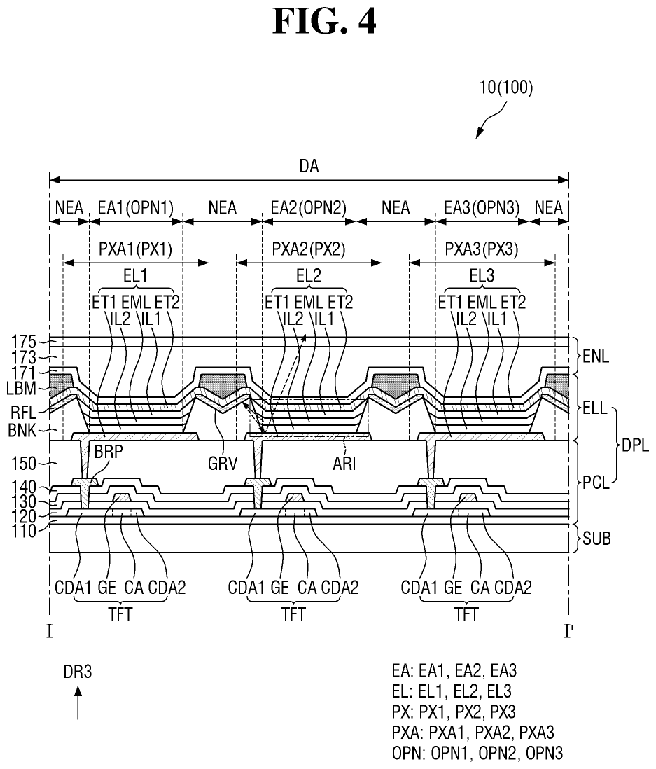

In some embodiments, each pixel PX may be a self-emitting pixel including at least one light emitting element (e.g., a light emitting element EL of FIG. 4). In an embodiment, the pixel PX may be a quantum dot light emitting element (e.g., a quantum dot light emitting diode) including a quantum dot light emitting layer.

The pixel PX may further include a pixel driving unit (e.g., a pixel circuit) for controlling a driving current flowing to the light emitting element. In this case, the pixel PX may further include at least one circuit element (e.g., transistors including a switching transistor and a driving transistor and at least one capacitor) constituting the pixel driving unit.

The first driving unit 200 and the second driving unit 300 may generate driving signals for controlling operation timings, emission luminance, and the like, of the pixels PX, and may supply the driving signals to the pixels PX. For example, the first driving unit 200 may be a gate driver including a scan driver, and may supply respective gate signals (e.g., gate signals including scan signals) to the pixels PX. The second driving unit 300 may be a source driver including a data driver, and may supply data signals to the pixels PX.

In an embodiment, at least one of the first driving units 200 and the second driving units 300 or portions of the at least one driving unit may be embedded in the display panel 100. For example, the first driving units 200 (or portions of the first driving units 200) may be disposed or formed in the non-display area NDA of the display panel 100.

It has been illustrated in FIG. 1 that the first driving units 200 are disposed in the non-display areas NDA positioned on both sides of the display area DA, but positions of the first driving units 200 are not limited thereto. For example, the first driving unit 200 may also be positioned only on one side (e.g., the left or the right side) of the display area DA. In another embodiment, portions of the first driving units 200 (e.g., some of circuit elements constituting the first driving units 200) may be positioned in the non-display area NDA, and the other portions of the first driving units 200 (e.g., the others of the circuit elements constituting the first driving units 200) may be positioned in a non-emission area (e.g., an area between emission areas of the pixels PX) provided in the display area DA. In still another embodiment, the first driving units 200 may be disposed or formed outside the display panel 100 and electrically connected to the display panel 100.

In an embodiment, the other of the first driving units 200 and the second driving units 300 or portions of the other driving unit may be disposed or formed outside the display panel 100 and electrically connected to the display panel 100. For example, the second driving units 300 (or portions of the second driving unit 300) may be implemented as a plurality of integrated circuit chips and may be disposed on circuit boards 400 (e.g., flexible circuit boards) electrically connected to the pixels PX of the display panel 100.

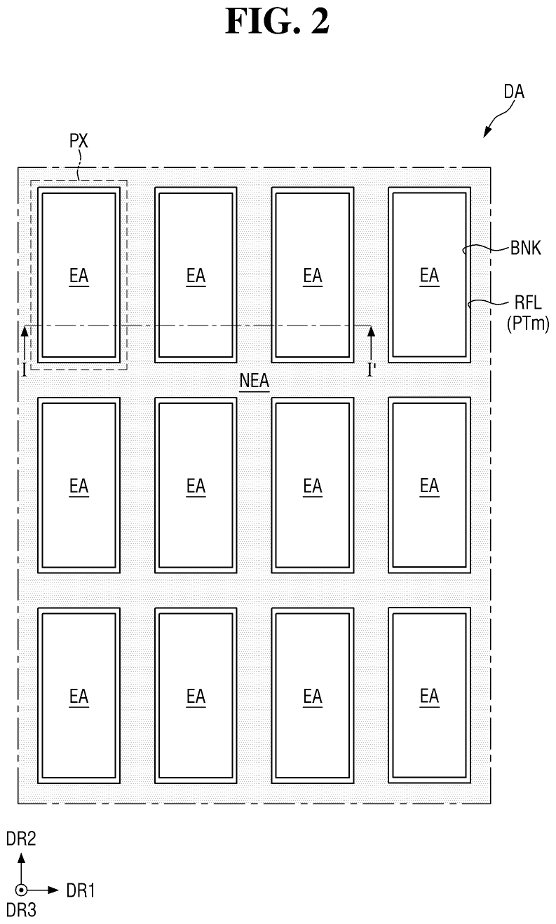

FIG. 2 is a plan view illustrating a display area DA of the display device 10 according to an embodiment. For example, FIG. 2 schematically illustrates a portion of the display area DA illustrated in FIG. 1.

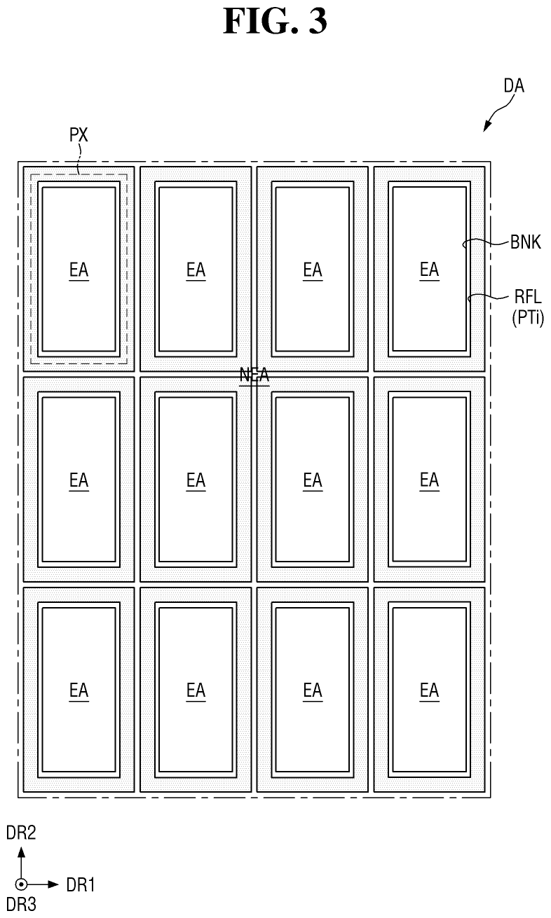

FIG. 3 is a plan view illustrating a display area DA of the display device 10 according to an embodiment. For example, FIG. 3 schematically illustrates a portion of the display area DA illustrated in FIG. 1. FIGS. 2 and 3 illustrate different embodiments in relation to a reflective layer RFL.

Referring to FIGS. 2 and 3 in addition to FIG. 1, pixels PX including respective emission areas EA may be disposed in the display area DA. For example, each pixel PX may include at least one emission area EA and a peripheral area positioned around the emission area EA.

It has been illustrated in FIGS. 2 and 3 that the emission areas EA of the pixels PX have substantially the same or similar shapes and sizes, but embodiments are not limited thereto. For example, the pixels PX may include at least two groups (e.g., first color pixels, second color pixels, and/or third color pixels), and may include emission areas EA having different sizes and/or shapes for each group. In addition, the pixels PX may be arranged in the display area DA in various arrangement structures and/or ratios according to embodiments.

The emission area EA is an area in which a light emitting element of the pixel PX is disposed or formed, and may be, for example, an area in which a light emitting layer of the light emitting element is positioned. The emission area EA may be a light transmitting area formed so that light may be emitted toward at least a display surface (e.g., an upper surface of the display panel 100). A bank BNK and a reflective layer RFL may not be provided in the emission area EA. For example, the bank BNK and the reflective layer RFL may be opened in the emission area EA.

In a pixel area in which each pixel PX is disposed or formed, an area other than the emission area EA may be a peripheral area. The peripheral area may be an area directly adjacent to an emission area EA of the corresponding pixel PX, and may be a non-emission area NEA.

For example, the display area DA may include the emission areas EA of the pixels PX and the non-emission area NEA surrounding the emission areas EA. The emission areas EA of the pixels PX may be spaced apart from each other with a portion of the non-emission area NEA interposed therebetween.

Each pixel area may include a light emitting element area in which a light emitting element of the corresponding pixel PX is disposed or formed (e.g., a light emitting element area defined based on a first electrode, a light emitting layer, or the like, of the light emitting element as an area including at least the emission area EA of the corresponding pixel PX). In an embodiment, each pixel area may further include a pixel circuit area in which circuit elements constituting a pixel driving unit (e.g., a pixel circuit) of the corresponding pixel PX are disposed or formed. The emission area EA of each pixel PX and the pixel circuit area may or may not overlap each other.

In the display area DA, the bank BNK and the reflective layer RFL positioned in the non-emission area NEA may be further disposed to surround the emission areas EA of the pixels PX. The bank BNK and the reflective layer RFL may overlap each other. For example, the reflective layer RFL may be positioned on at least a portion of the bank BNK (e.g., a portion where a groove GRV of FIG. 4 is formed).

The bank BNK may have openings to expose the emission areas EA of the pixels PX, and may surround the emission areas EA around the emission areas EA. For example, the bank BNK may be positioned in a peripheral area between and/or around the emission areas EA so as to surround each of the emission areas EA of the pixels PX.

In an embodiment, the bank BNK may include or may be a mesh-shaped pattern layer having the openings corresponding to the emission areas EA of the pixels PX and surrounding each of the emission areas EA of the pixels PX. The bank BNK may be formed to be connected as a whole within the display area DA or may be formed to be connected within a plurality of sub-areas partitioned within the display area DA for each of the plurality of sub-areas.

The reflective layer RFL may be disposed on at least a portion of the bank BNK and surround the emission areas EA of the pixels PX. For example, the reflective layer RFL may have openings corresponding to the emission areas EA of the pixels PX, and may completely surround each of the emission areas EA of the pixels PX in a plan view. In an embodiment, the reflective layer RFL may have a shape surrounding the emission areas EA of the pixels PX (e.g., a shape including a perimeter corresponding to the emission areas EA of the pixels PX), but is not limited thereto.

In an embodiment, the reflective layer RFL may include a mesh-shaped pattern PTm (e.g., a mesh-shaped integrated pattern layer) including openings corresponding to the emission areas EA of the pixels PX and disposed in the non-emission area NEA, as illustrated in FIG. 2. The mesh-shaped pattern PTm may be formed to be connected as a whole within the display area DA or may be formed to be connected within the plurality of sub-areas partitioned within the display area DA for each of the plurality of sub-areas. For example, the reflective layer RFL may be formed of a same material and are formed in one piece throughout the display area DA and may surround each of the emission areas EA while having openings corresponding to the emission areas EA.

In another embodiment, the reflective layer RFL may include a plurality of reflective patterns PTi each of which has an opening corresponding to the emission area EA of a corresponding pixel PX. The plurality of reflective patterns PTi may be separated from each other in the peripheral areas of the pixels PX and/or between the pixels PX, as illustrated in FIG. 3. For example, the reflective layer RFL may include at least two separate reflective patterns PTi individually surrounding each of the emission areas EA of the pixels PX and separated from each other.

FIG. 4 is a cross-sectional view illustrating the display device 10 according to an embodiment. For example, FIG. 4 illustrates a cross-section of a portion of the display panel 100 including the display area DA, and illustrates an embodiment of a cross-section of the display panel 100 taken along line I-I′ in FIG. 2.

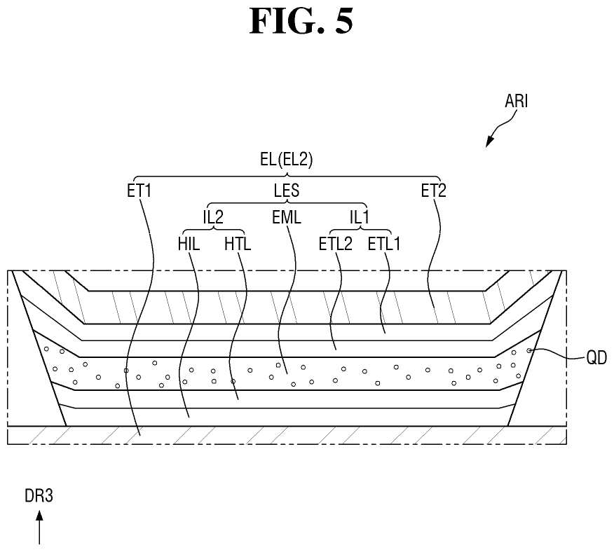

FIG. 5 is a cross-sectional view illustrating a light emitting element EL according to an embodiment. For example, FIG. 5 illustrates an embodiment of a cross section of a light emitting element EL (e.g., a second light emitting element EL2) corresponding to area ARI of FIG. 4. In an embodiment, the light emitting elements EL provided in the pixels PX may have a substantially similar or identical structure.

Referring to FIGS. 4 and 5 in addition to FIGS. 1 to 3, the display device 10 (or the display panel 100) may include a substrate SUB, a display layer DPL, and an encapsulation layer ENL disposed on the display layer DPL. In an embodiment, the display layer DPL may include a panel circuit layer PCL and a light emitting element layer ELL.

In an embodiment, the display device 10 may further include additional components. For example, the display device 10 may further include at least one of a protective layer (e.g., a window and/or a protective film) disposed on the encapsulation layer ENL and an optical filter (e.g., a color filter layer) disposed above or below the encapsulation layer ENL. The protective layer and/or the optical filter may be provided or formed integrally with the display panel 100 or may be provided separately from the display panel 100 and be disposed on the display panel 100.

The substrate SUB is a base member (or a base layer) of the display panel 100 and may be rigid or flexible. In an embodiment, the substrate SUB may be one of a glass substrate, a quartz substrate, a glass ceramic substrate, a film substrate including a polymer organic material, and a plastic substrate, but is not limited thereto.

A display area DA and a non-display area NDA may be defined on the substrate SUB. The display area DA may include emission areas EA corresponding to openings OPN of the bank BNK and having respective light emitting elements EL disposed therein and a non-emission area NEA surrounding the emission areas EA.

The panel circuit layer PCL (e.g., a pixel circuit layer or a thin film transistor layer) may be disposed on the substrate SUB. The panel circuit layer PCL may include a barrier film 110 (or a buffer layer) and circuit elements (e.g., transistors and a capacitor constituting a pixel circuit of each of the pixels PX) and/or signal lines disposed on the barrier film 110. For convenience, in FIG. 4, transistors (e.g., thin film transistors TFT) disposed in pixel areas PXA of the respective pixels PX and electrically connected to the light emitting elements EL of the corresponding pixels PX have been illustrated as an example of elements that may be disposed on the panel circuit layer PCL.

The barrier film 110 may be disposed on the substrate SUB. The barrier film 110 may include an inorganic insulating material including silicon nitride, silicon oxide, silicon oxynitride, or the like, or other insulating materials.

An active layer (or a semiconductor pattern) of each of the transistors TFT may be disposed on the barrier film 110. The active layer may include polycrystalline silicon, single crystal silicon, low-temperature polycrystalline silicon, amorphous silicon, an oxide semiconductor, or other semiconductor materials.

The active layer of the transistor TFT may include a channel region CA, a first conductive region CDA1, and a second conductive region CDA2. The first conductive region CDA1 and the second conductive region CDA2 may be spaced apart from each other with the channel region CA interposed therebetween.

The channel region CA may overlap a gate electrode GE. At least a portion of each of the first conductive region CDA1 and the second conductive region CDA2 may not overlap the gate electrode GE.

The first conductive region CDA1 and the second conductive region CDA2 may be regions heavily doped with impurities to have conductivity. In an embodiment, one of the first conductive region CDA1 and the second conductive region CDA2 may be a source region, and the other of the first conductive region CDA1 and the second conductive region CDA2 may be a drain region. In an embodiment, one of the first conductive region CDA1 and the second conductive region CDA2 may function as a source electrode, and the other of the first conductive region CDA1 and the second conductive region CDA2 may function as a drain electrode. In another embodiment, each of the transistors TFT may further include a separate source electrode and/or a drain electrode electrically connected to the first conductive region CDA1 or the second conductive region CDA2.

In an embodiment, a light blocking pattern may be disposed below at least one of the transistors TFT provided in the respective pixels PX. For example, the panel circuit layer PCL may further include at least one light blocking pattern disposed between the substrate SUB and the barrier film 110 and overlapping the active layer of the at least one transistor TFT.

A first insulating film 120 (e.g., a gate insulating film) may be disposed on the active layers of the transistors TFT. In an embodiment, the first insulating film 120 may include an inorganic insulating layer of at least one layer including an inorganic insulating material.

The gate electrode GE of each of the transistors TFT may be disposed on the first insulating film 120. In an embodiment, the gate electrode GE may include any one of molybdenum (Mo), aluminum (Al), chromium (Cr), gold (Au), titanium (Ti), nickel (Ni), neodymium (Nd), and copper (Cu), or alloys thereof. The gate electrode GE may include other conductive materials. In an embodiment, a first electrode of a capacitor provided in each pixel PX, at least one line, and the like, may be further disposed on the first insulating film 120.

A second insulating film 130 (e.g., a first interlayer insulating film) may be disposed on the gate electrodes GE of the transistors TFT. In an embodiment, the second insulating film 130 may include an inorganic insulating layer of at least one layer including an inorganic insulating material. In an embodiment, a second electrode of the capacitor provided in each pixel PX, at least one signal line, and the like, may be further disposed on the second insulating film 130. In an embodiment, a source electrode and/or a drain electrode of at least one transistor TFT may be further disposed on the second insulating film 130.

A third insulating film 140 (e.g., a second interlayer insulating film) may be disposed on the second insulating film 130, the second electrode of the capacitor, and/or at least one signal line. In an embodiment, the third insulating film 140 may include an inorganic insulating layer of at least one layer including an inorganic insulating material. In an embodiment, the second electrode of the capacitor provided in the pixel PX may be disposed at the same layer as connection electrodes BRP (or bridge patterns), and the third insulating film 140 may be omitted.

The connection electrodes BRP may be disposed on the third insulating film 140. The connection electrodes BRP may be connected to the first conductive regions CDA1 (or the second conductive regions CDA2) of the respective transistors TFT through respective contact holes formed through the first insulating film 120, the second insulating film 130, and the third insulating film 140. An embodiment in which the connection electrodes BRP are formed in a single-layer structure has been illustrated in FIG. 4, but embodiments are not limited thereto. For example, the connection electrodes BRP may be formed in a multilayer structure. The connection electrodes BRP may include any one of molybdenum (Mo), aluminum (Al), chromium (Cr), gold (Au), titanium (Ti), nickel (Ni), neodymium (Nd), and copper (Cu), alloys thereof, or other conductive materials.

A fourth insulating film 150 (e.g., a planarization film) may be disposed on the connection electrodes BRP. In an embodiment, the fourth insulating film 150 may include an organic insulating layer of at least one layer including an acrylic resin, an epoxy resin, a phenolic resin, a polyamide resin, a polyimide resin, or other organic insulating materials. The fourth insulating film 150 may planarize a step due to the transistors TFT.

The light emitting element layer ELL may be disposed on the fourth insulating film 150. The light emitting element layer ELL may include the light emitting elements EL of the pixels PX, the bank BNK, and the reflective layer RFL. In an embodiment, the light emitting element layer ELL may further include a light blocking layer LBM.

Each light emitting element EL may include a first electrode ET1 (or a pixel electrode), a light emitting layer EML, and a second electrode ET2 (or a common electrode). One of the first electrode ET1 and the second electrode ET2 may be an anode electrode, and the other of the first electrode ET1 and the second electrode ET2 may be a cathode electrode. For example, when the first electrode ET1 is an anode electrode, the second electrode ET2 may be a cathode electrode. Conversely, when the first electrode ET1 is a cathode electrode, the second electrode ET2 may be an anode electrode.

Each light emitting element EL may further include at least one intermediate layer. For example, each light emitting element EL may further include at least one of a first intermediate layer IL1 and a second intermediate layer IL2. The first intermediate layer IL1 may be disposed between the light emitting layer EML and the second electrode ET2, and the second intermediate layer IL2 may be disposed between the light emitting layer EML and the first electrode ET1. One of the first intermediate layer IL1 and the second intermediate layer IL2 may be an electron layer, and the other of the first intermediate layer IL1 and the second intermediate layer IL2 may be a hole layer. For example, when the first intermediate layer IL1 is an electron layer, the second intermediate layer IL2 may be a hole layer. Conversely, when the first intermediate layer IL1 is a hole layer, the second intermediate layer IL2 may be an electron layer.

The light emitting layer EML, the first intermediate layer IL1, and/or the second intermediate layer IL2 may configure a light emitting stack LES interposed between the first electrode ET1 and the second electrode ET2. For example, the light emitting stack LES may include the light emitting layer EML and at least one intermediate layer disposed to overlap each other between the first electrode ET1 and the second electrode ET2.

The first electrode ET1 of each of the light emitting elements EL may be positioned in the pixel area PXA of the corresponding pixel PX and may be disposed on the fourth insulating film 150. For example, a first electrode ET1 of a light emitting element EL of a first pixel PX1 (hereinafter referred to as a “first light emitting element EL1”) may be positioned in a first pixel area PXA1 in which the first pixel PX1 is disposed or formed. A first electrode ET1 of a light emitting element EL of a second pixel PX2 (hereinafter referred to as a “second light emitting element EL2”) may be positioned in a second pixel area PXA2 in which the second pixel PX2 is disposed or formed. A first electrode ET1 of a light emitting element EL of a third pixel PX3 (hereinafter referred to as a “third light emitting element EL3”) may be positioned in a third pixel area PXA3 in which the third pixel PX3 is disposed or formed.

The first electrode ET1 of each of the light emitting elements EL may be positioned at least in an emission area EA of the corresponding pixel PX. For example, the first electrode ET1 of the first light emitting element EL1 may be positioned in an emission area EA of the first pixel PX1 (hereinafter referred to as a “first emission area EA1”). The first electrode ET1 of the second light emitting element EL2 may be positioned in an emission area EA of the second pixel PX2 (hereinafter referred to as a “second emission area EA2”). The first electrode ET1 of the third light emitting element EL3 may be positioned in an emission area EA of the third pixel PX3 (hereinafter referred to as a “third emission area EA3”).

In an embodiment, a portion of the first electrode ET1 may be positioned in the non-emission area NEA. For example, an edge area of the first electrode ET1 may be positioned in the non-emission area NEA around the emission area EA.

The first electrode ET1 of each of the light emitting elements EL may be connected to the circuit elements and/or the connection electrode BRP provided in the corresponding pixel PX. For example, the first electrode ET1 of each of the light emitting elements EL may be electrically connected to the transistor TFT constituting the pixel circuit of the corresponding pixel PX through the connection electrode BRP. In another embodiment, the connection electrode BRP is not provided in the pixel PX, and the first electrode ET1 may be directly connected to the transistor TFT through at least one contact hole.

In an embodiment, the first electrode ET1 may be a reflective electrode. For example, the first electrode ET1 may include a reflective electrode layer including at least one material of aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), and chromium (Cr) or other reflective conductive materials.

In an embodiment, the first electrode ET1 may have a multilayer structure including a reflective electrode layer. For example, the first electrode ET1 may include a reflective electrode layer and a conductive oxide layer formed on the reflective electrode layer. In an embodiment, the conductive oxide layer may be made of, for example, indium-tin-oxide (ITO), indium-zinc-oxide (IZO), indium-tin-zinc-oxide (ITZO), zinc oxide (ZnO), indium oxide (In₂O₃), indium-gallium-oxide (IGO), or aluminum-zinc-oxide (AZO), but is not limited thereto. In an embodiment, the first electrode ET1 may have a multilayer structure of ITO/Mg, ITO/MgF, ITO/Ag, or ITO/Ag/ITO, but is not limited thereto.

The bank BNK may be disposed on the first electrodes ET1 of the light emitting elements EL. For example, the bank BNK may be formed in the non-emission area NEA to overlap edge areas of the first electrodes ET1, and may include openings OPN exposing a portion of each of the first electrodes ET1. As an example, the bank BNK may include a first opening OPN1 exposing the first electrode ET1 of the first light emitting element EL1, a second opening OPN2 exposing the first electrode ET1 of the second light emitting element EL2, and a third opening OPN3 exposing the first electrode ET1 of the third light emitting element EL3.

An area in which each exposed first electrode ET1 and the light emitting layer EML overlap each other (or an area including such an area) is an area in which the light emitting stack LES of the light emitting element EL is disposed or formed, and may be defined as an emission area EA of each pixel PX. For example, the first pixel PX1 may include the first emission area EA1 corresponding to the first opening OPN1 of the bank BNK (e.g., positioned in the first opening OPN1). The second pixel PX2 may include the second emission area EA2 corresponding to the second opening OPN2 of the bank BNK. The third pixel PX3 may include the third emission area EA3 corresponding to the third opening OPN3 of the bank BNK.

Light generated from each light emitting element EL may be emitted from each emission area EA. In an embodiment, when the first electrode ET1 of the light emitting element EL includes the reflective electrode layer and the second electrode ET2 includes a transparent electrode layer (or a translucent electrode layer), the light emitted from the light emitting layer EML of the light emitting element EL may be transmitted through the second electrode ET2 and be emitted in an upward direction of the light emitting layer EML. As an example, the light emitted from the light emitting layer EML may be emitted in the third direction DR3 toward an upper portion of the substrate SUB.

In an embodiment, the bank BNK may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB). Alternatively, the bank BNK may also include an inorganic material such as silicon nitride. A material of the bank BNK may be changed according to embodiments. The bank BNK may have a single-layer structure or a multilayer structure.

In an embodiment, the bank BNK may include a liquid repellent material or may be surface-treated so that a surface thereof has hydrophobicity. Accordingly, when the light emitting stack LES is formed in each emission area EA by an inkjet printing process or the like, ink including a light emitting material and the like may stably flow into each emission area EA.

In an embodiment, the bank BNK may include grooves GRV (or valleys) at least in an upper surface thereof. For example, the bank BNK may include at least one V-shaped groove GRV in an area disposed between adjacent emission areas EA. As an example, the bank BNK may include one V-shaped groove GRV between the first emission area EA1 and the second emission area EA2 and one V-shape groove GRV between the second emission area EA2 and the third emission area EA3 in cross section.

In an embodiment, the groove GRV may completely surround each emission area EA in a plan view. However, embodiments are not limited thereto. For example, the groove GRV may partially surround each emission area EA in a plan view.

The reflective layer RFL may be disposed on the bank BNK. For example, the reflective layer RFL may be disposed on at least portions of the bank BNK including the grooves GRV (e.g., the upper surface of the bank BNK including the grooves GRV).

In an embodiment, the reflective layer RFL may include a reflective material. For example, the reflective layer RFL may include a reflective metal layer including at least one metal of aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), and chromium (Cr) or other metals, and may be formed in a single-layer structure or a multilayer structure. Alternatively, the reflective layer RFL may include a low refractive index layer including a low refractive material having a relatively lower refractive index than the bank BNK, and may be formed in a single-layer structure or a multilayer structure including the low refractive index layer. For example, the reflective layer RFL may include a low refractive index layer having a reflective index within a range in which light (for example, light of ultraviolet and/or visible ray wavelength bands) transmitted through the bank BNK and reaching the reflective layer RFL may be reflected on an interface between the reflective layer RFL and the bank BNK.

The reflective layer RFL may have curved surfaces or inclined surfaces corresponding to the grooves GRV of the bank BNK. As an example, the reflective layer RFL may be disposed on inclined surfaces corresponding to the grooves GRV of the bank BNK to have inclined surfaces corresponding to the grooves GRV. As an example, when the bank BNK includes at least one V-shaped groove GRV between neighboring emission areas EA, the reflective layer RFL may have a V shape between the neighboring emission areas EA in a cross-sectional view.

In an embodiment, the reflective layer RFL may be disposed and/or formed higher than the light emitting stack LES of each of the light emitting elements EL. For example, at least a portion of the reflective layer RFL may be positioned at a height equal to or higher than the highest height of the light emitting stack LES. Accordingly, the light reflected from the reflective layer RFL may be incident on the surrounding light emitting stacks LES to improve characteristics of the light emitting elements EL and increase luminous efficiency of the light emitting elements EL.

For example, the reflective layer RFL may reflect ultraviolet (UV) light irradiated from below the substrate SUB to the emission area EA in which each light emitting stack LES is formed during a process of manufacturing the display device 10. Accordingly, characteristics of the light emitting stack LES may be adjusted. As an example, a defect of at least one electron transport layer (e.g., a first electron transport layer ETL1 including ZnO) included in the first intermediate layer IL1 may be improved by the irradiation of the UV light to lower resistance of the electron transport layer. Accordingly, luminous efficiency of the light emitting element EL may be increased.

The reflective layer RFL may reflect light traveling toward the non-emission area NEA among light emitted from the respective light emitting stacks LES to the emission areas EA to recirculate the light during actual use of the display device 10. For example, as indicated by a dotted arrow in FIG. 4, light emitted from the light emitting layers EML of the light emitting elements EL and traveling toward the non-emission area NEA may be sequentially reflected from the reflective layer RFL and the first electrodes ET1 and be emitted to upper portions of the pixels PX. Accordingly, light loss of the pixels PX is reduced or minimized, such that luminous efficiency of the pixels PX and the display device 10 including the pixels PX may be increased.

The light emitting stack LES may be disposed on the first electrode ET1 of the light emitting element EL exposed by each opening OPN of the bank BNK. The light emitting stack LES may be surrounded by the bank BNK and/or the reflective layer RFL.

The light emitting stack LES may include the light emitting layer EML and at least one intermediate layer. For example, the light emitting stack LES may include the second intermediate layer IL2, the light emitting layer EML, and the first intermediate layer IL1 sequentially disposed and/or stacked on the first electrode ET1 along the third direction DR3.

The second intermediate layer IL2 may include at least one hole layer or electron layer. For example, when the second intermediate layer IL2 is disposed between the light emitting layer EML and the first electrode ET1 and the first electrode ET1 is the anode electrode, the second intermediate layer IL2 may be a hole layer including at least one of a hole injection layer HIL and a hole transport layer HTL. The hole layer may include an inorganic material or an organic material, and a structure and/or a material of the hole layer may be changed according to embodiments.

The hole injection layer HIL may be positioned between the first electrode ET1 and the hole transport layer HTL (or between the first electrode ET1 and the light emitting layer EML). The hole transport layer HTL may be positioned between the hole injection layer HIL and the light emitting layer EML (or between the first electrode ET1 and the light emitting layer EML).

In an embodiment, the hole injection layer HIL may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), polyether ketone containing triphenylamine (TPAPEK), 4-isopropyl-4′-methyldiphenyliodonium [tetrakis(pentafluorophenyl) borate], dipyrazino [2,3-f: 2′,3′-h] quinoxaline-2,3,6,7,10,11-hexacarbonitrile (HAT-CN), or the like.

In an embodiment, the hole transport layer HTL may include carbazole-based derivatives such as N-phenylcarbazole and polyvinylcarbazole, fluorene-based derivatives, triphenylamine-based derivatives such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(naphthalene-1-yl)-N,N′-diphenyl-benzidine (NPD), 4,4′-cyclohexylidene bis [N,N-bis(4-methylphenyl)benzenamine] (TAPC), 4,4′-bis [N,N′-(3-tolyl)amino]-3,3′-dimethylbiphenyl (HMTPD), 1,3-bis(N-carbazolyl)benzene (mCP), or the like.

In an embodiment, the hole injection layer HIL and/or the hole transport layer HTL may be an inorganic hole layer including a metal oxide or other inorganic materials. For example, the hole injection layer HIL and/or the hole transport layer HTL may include a metal oxide including at least one metal of molybdenum (Mo), tungsten (W), vanadium (V), niobium (Nb), and tantalum (Ta) or other metals.

In addition, a material of each of the hole injection layer HIL and the hole transport layer HTL may be variously changed according to embodiments. In addition, the hole injection layer HIL and the hole transport layer HTL may include the same material or may include different materials.

In an embodiment, the second intermediate layer IL2 may be formed by an inkjet printing process. For example, each of the hole injection layer HIL and the hole transport layer HTL may be formed by applying a solution in which a material (e.g., a metal oxide) to be used for forming the hole injection layer HIL or the hole transport layer HTL is dispersed in a solvent containing an organic material to each emission area EA using a method such as an inkjet printing process and then volatilizing the solvent. In an embodiment, the second intermediate layer IL2 may further include an additive for dispersion stability of the metal oxide dispersed in the solvent. However, a method for forming the second intermediate layer IL2 is not limited thereto. For example, the second intermediate layer IL2 may also be formed using other methods such as a vacuum deposition method, a spin coating method, a cast method, a Langmuir-Blodgett (LB) method, a laser printing method, and a laser induced thermal imaging (LITI) method.

The light emitting layer EML may include a high molecular material or a low molecular material. The light emitted from the light emitting layer EML may contribute to image display. In an embodiment, the light emitting layer EML may be provided for each pixel PX, and the light emitting layer of each pixel PX may emit a visible ray of a color corresponding to the corresponding pixel PX. In another embodiment, the light emitting layers EML of the pixels PX may emit light of the same specific color, and wavelength conversion layers corresponding to colors (or wavelength bands) of light to be emitted from the respective pixels PX may be disposed in the emission areas EA of at least some of the pixels PX.

In an embodiment, the light emitting layer EML may be a quantum dot light emitting layer including quantum dots QD. In this case, each light emitting element EL may be a quantum dot light emitting diode.

For example, the light emitting layer EML may include quantum dots QD having a core-shell structure. In an embodiment, the core of the quantum dot QD may be selected from a group II-VI compound, a group III-V compound, a group IV-VI compound, a group IV element, a group IV compound, and combinations thereof.

The group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group III-V compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAINP, and mixtures thereof; and a quaternary compound selected from the group consisting of GaAINAs, GaAINSb, GaAlPAs, GaAlPSb, GaInNP, GaInNAs, GaInNSb, GalnPAs, GaInPSb, InAlNP, InAlNAs, InAlNSb, InAlPAs, InAlPSb, and mixtures thereof.

The group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

The group IV element may be selected from the group consisting of Si, Ge, and mixtures thereof.

The group IV compound may be a binary compound selected from the group consisting of SiC, SiGe, and mixtures thereof.

The binary compound, the ternary compound, or the quaternary compound may be present in a particle at a uniform concentration or may be present in the same particle in a state of partially different concentration distributions. In addition, one quantum dot QD may have a core-shell structure surrounding another quantum dot QD. An interface between a core and a shell may have a concentration gradient in which a concentration of elements present in the shell decreases toward the center.

In an embodiment, the quantum dot QD may have a core-shell structure including a core including nanocrystals and a shell surrounding the core. The shell of the quantum dot QD may serve as a protective layer for maintaining semiconductor characteristics by preventing chemical modification of the core and/or serve as a charging layer for imparting electrophoretic characteristics to the quantum dot QD. The shell may be a single layer or multiple layers. An interface between a core and a shell may have a concentration gradient in which a concentration of elements present in the shell decreases toward the center. Examples of the shell of the quantum dot QD may include a metal or non-metal oxide, a semiconductor compound, combinations thereof, or the like. Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the present disclosure is not limited thereto. In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the present disclosure is not limited thereto.

The quantum dot QD may have a full width of half maximum (FWHM) of an emission wavelength spectrum of about 45 nm or less, preferably about 40 nm or less, and more preferably about 30 nm or less, and may improve color purity or color reproducibility in such a range. Light emitted through such quantum dots QD is emitted in all directions, and thus, a wide viewing angle may be realized.

Shapes of the quantum dots QD are not particularly limited as long as the quantum dots QD are generally in the art, but more specifically, quantum dots QD in the form of spherical, pyramidal, multi-arm, or cubic nanoparticles, nanotubes, nanowires, nanofibers, or nanoplate particles may be used.

The quantum dots QD may control colors of emitted light according to particle sizes. Accordingly, the quantum dots QD may have various emission colors such as blue, red, and green.

In an embodiment, the first to third light emitting elements EL1, EL2, and EL3 may emit light of different colors and/or wavelengths depending on sizes of the quantum dots QD included in the respective light emitting layers EML. For example, the light emitting layer EML of the first light emitting element EL1 may emit red light, the light emitting layer EML of the second light emitting element EL2 may emit green light, and the light emitting layer EML of the third light emitting element EL3 may emit blue light.

In an embodiment, the light emitting layer EML of each of the first to third light emitting elements EL1, EL2, and EL3 may be formed by an inkjet printing process. For example, the light emitting layer EML of each of the first to third light emitting elements EL1, EL2, and EL3 may be formed by dispersing the quantum dots QD in a solvent, applying a solution in which the quantum dots QD are dispersed in the solvent to each emission area EA using a method such as an inkjet printing process and then volatilizing the solvent. However, a method for forming the light emitting layer EML is not limited thereto. For example, the light emitting layer EML may be formed using various methods such as a vacuum deposition method, a spin coating method, a cast method, an LB (Langmuir-Blodgett) method, a laser printing method, and an LITI (Laser Induced Thermal Imaging) method.

The first intermediate layer IL1 may include at least one electron layer or hole layer overlapping the light emitting layer EML. For example, when the first intermediate layer IL1 is disposed between the light emitting layer EML and the second electrode ET2 and the second electrode ET2 is the cathode electrode, the first intermediate layer IL1 may be an electron layer including at least one of an electron transport layer and an electron injection layer. In an embodiment, the first intermediate layer IL1 may include at least one of a first electron transport layer ETL1 and a second electron transport layer ETL2.

The first electron transport layer ETL1 may be positioned between the second electrode ET2 and the second electron transport layer ETL2 (or between the second electrode ET2 and the light emitting layer EML). The second electron transport layer ETL2 may be positioned between the first electron transport layer ETL1 and the light emitting layer EML (or between the second electrode ET2 and the light emitting layer EML).

In an embodiment, the first intermediate layer IL1 may be an inorganic electron layer including an inorganic material. For example, each of the first electron transport layer ETL1 and the second electron transport layer ETL2 may include a metal oxide including at least one metal of an alkaline earth metal, a transition metal, a Group XIII metal, and a Group XIIII metal, or other metals. Examples of the metal in the metal oxide may include Zn, Ti, Zr, Sn, W, Ta, Ni, Mo, Cu, Mg, Co, Mn, Y, Al or any combinations thereof, but embodiments are not limited thereto.

In an embodiment, the first intermediate layer IL1 may include zinc oxide. A type of the zinc oxide is not particularly limited, but may be, for example, ZnO, ZnO doped with Mg (ZnMgO), or combinations thereof, and may be ZnO doped with Li, Y, and the like, in addition to Mg. However, embodiments are not limited thereto. For example, zinc oxide may also be included in the second intermediate layer IL2.

In an embodiment, zinc oxide may be included in two or more layers included in the first intermediate layer IL1. For example, the first intermediate layer IL1 may have a multilayer structure including a first electron transport layer ETL1 including ZnO and a second electron transport layer ETL2 including ZnMgO.

In an embodiment, the first intermediate layer IL1 may be formed by an inkjet printing process. For example, each of the first electron transport layer ETL1 and the second electron transport layer ETL2 may be formed by applying a solution in which a material to be used for forming the first electron transport layer ETL1 or the second electron transport layer ETL2 (e.g., ZnO or other metal oxides) is dispersed in a solvent including an organic material to each emission area EA using a method such as an inkjet printing process and then volatilizing the solvent. In an embodiment, the first intermediate layer IL1 may further include an additive for dispersion stability of the metal oxide dispersed in the solvent. However, a method for forming the first intermediate layer IL1 is not limited thereto. For example, the first intermediate layer IL1 may be formed using other methods such as a vacuum deposition method, a spin coating method, a cast method, an LB method, a laser printing method, and an LITI method.

According to an embodiment, in case that each layer of the light emitting stack LES is formed by the inkjet printing process, a manufacturing cost of the display device 10 may be reduced. However, due to a coffee ring effect occurring in a drying process such as baking, thicknesses and/or heights of the light emitting stack LES and the respective layers constituting the light emitting stack LES may not be uniform. For example, the light emitting stack LES and the respective layers constituting the light emitting stack LES (e.g., the hole injection layer HIL, the hole transport layer HTL, the light emitting layer EML, the second electron transport layer ETL2, and/or the first electron transport layer ETL1) may have greater thicknesses and/or heights in an edge area adjacent to the bank BNK than in other areas (e.g., a center of the light emitting stack LES). For this reason, light emitting characteristics (e.g., luminous efficiency and light emitting quality) of the light emitting element EL and the pixel PX including the light emitting element EL may be decreased.

For example, the first intermediate layer IL1 and/or the second intermediate layer IL2 may have non-uniform thicknesses in each emission area EA, and resistance may be increased due to a difference in thickness, such that efficiency of the light emitting stack LES may decrease. In addition, in each emission area EA, current non-uniformity occurs due to the non-uniform thicknesses of the first intermediate layer IL1, the second intermediate layer IL2, and the like, and an intensity and/or a brightness of light may be different for each area. For example, in an edge area of the emission area EA, the light emitting element EL may not emit light with sufficient luminance. Accordingly, luminance and/or an effective emission area of the light emitting element EL may decrease.

However, the display device 10 according to an embodiment may improve resistance of the light emitting stack LES (e.g., the first electron transport layer ETL1 including ZnO) during a process for manufacturing the pixel PX and recirculate the light traveling toward the non-emission area NEA during actual use of the pixel PX by including the reflective layer RFL disposed on the bank BNK. Accordingly, luminous efficiency of the light emitting element EL and the pixel PX including the light emitting element EL may increase, and light emitting quality of the light emitting element EL and the pixel PX including the light emitting element EL may be improved.

The second electrode ET2 may be disposed on the light emitting stack LES. For example, the second electrode ET2 may be disposed on the first intermediate layer IL1. In an embodiment, the second electrode ET2 may be a common electrode shared by the light emitting elements EL of the pixels PX, and may be entirely formed in the display area DA via an upper portion of the reflective layer RFL. For example, the second electrode ET2 may be disposed over the entirety of the emission areas EA and the non-emission area NEA to cover the light emitting elements EL and the reflective layer RFL.

In an embodiment, the second electrode ET2 may be in direct contact with the reflective layer RFL. When the reflective layer RFL includes a conductive material, the reflective layer RFL may also function as an auxiliary electrode of the second electrode ET2.

In an embodiment, the second electrode ET2 may be a transparent electrode that is substantially transparent. For example, the second electrode ET2 may include a transparent electrode layer including ITO, IZO, ITZO, AZO, or other transparent conductive materials. Alternatively, the second electrode ET2 may include a translucent electrode layer made of Li, Ca, LiF/Ca, LiF/Al, Al, Mg, or compounds thereof.

In an embodiment, the light emitting element layer ELL may further include a light blocking layer LBM disposed on the reflective layer RFL. For example, the light emitting element layer ELL may further include a light blocking layer LBM disposed in the non-emission area NEA to overlap the reflective layer RFL in a plan view. In an embodiment, the light blocking layer LBM may be disposed on the second electrode ET2, but a position of the light blocking layer LBM may be altered according to embodiments. As the light blocking layer LBM is disposed on the reflective layer RFL, external light reflection or the like in the non-emission area NEA may be reduced or prevented and image quality of the display device 10 may be improved.

In an embodiment, the light blocking layer LBM may have a mesh-shaped pattern having openings corresponding to the emission areas EA and surrounding the emission areas EA. For example, the light blocking layer LBM may have a size (e.g., a width and/or an area) and/or a shape substantially similar to or the same as those of the reflective layer RFL. In an embodiment, areas, positions, and the like of the openings of the light blocking layer LBM may be altered in consideration of light emission characteristics, viewing angles, or the like of the pixels PX.

The light blocking layer LBM may be formed of a material capable of blocking light. For example, the light blocking layer LBM may be formed of a photosensitive resin including an inorganic black pigment such as carbon black or an organic black pigment.

The encapsulation layer ENL may be disposed on the light emitting element layer ELL. In an embodiment, the encapsulation layer ENL may include at least one inorganic film and at least one organic film in order to prevent oxygen or moisture from permeating into the light emitting elements EL or protect the light emitting elements EL from foreign substances such as dust. For example, the encapsulation layer ENL may be formed in a structure in which a first inorganic film 171, an organic film 173, and a second inorganic film 175 are sequentially stacked. In an embodiment, the first inorganic film 171 and the second inorganic film 175 may include silicon nitride, silicon oxynitride, silicon oxide, titanium oxide, aluminum oxide, or other inorganic materials. In an embodiment, the organic film 173 may include an acrylic resin, an epoxy resin, a phenolic resin, a polyamide resin, a polyimide resin, or other organic materials.

An embodiment in which the light emitting element layer ELL and the like are encapsulated by the encapsulation layer ENL has been illustrated in FIG. 4, but embodiments are not limited thereto. For example, the light emitting element layer ELL and the like may be encapsulated using a separate upper substrate.

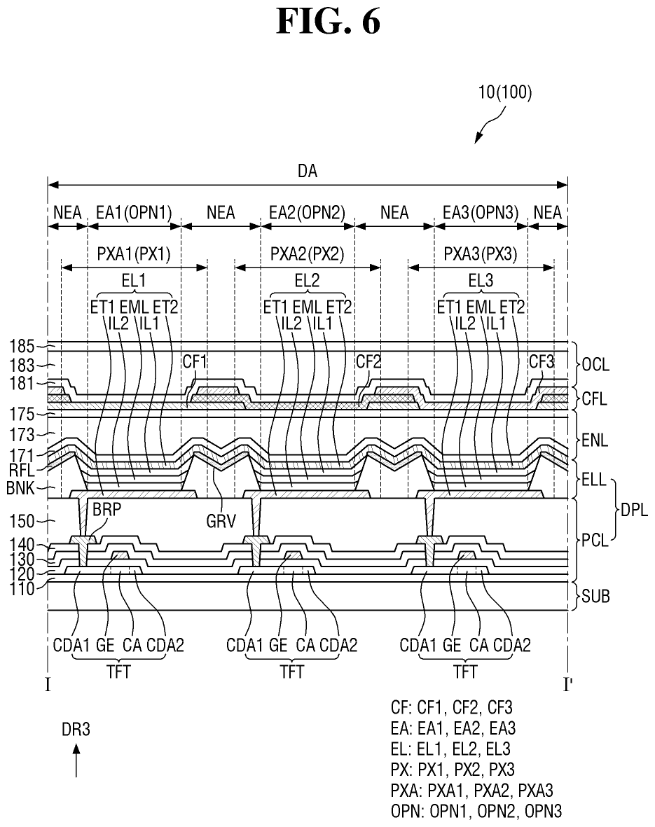

FIG. 6 is a cross-sectional view illustrating a display device 10 according to an embodiment. For example, FIG. 6 illustrates an embodiment of a cross section of the display device 10 corresponding to line I-I′ of FIG. 2. As compared with an embodiment of FIG. 4, the display device 10 according to an embodiment of FIG. 6 does not include the light blocking layer LBM and includes color filters CF overlapping each other in the non-emission area NEA.

Referring to FIG. 6 in addition to FIGS. 1 to 5, the display device 10 may not include the light blocking layer LBM disclosed in an embodiment of FIG. 4. Instead, the display device 10 may further include a color filter layer CFL and an overcoat layer OCL disposed above the light emitting element layer ELL. In an embodiment, the color filter layer CFL and the overcoat layer OCL may be disposed on the encapsulation layer ENL, but positions of the color filter layer CFL and/or the overcoat layer OCL may be altered according to embodiments.

The color filter layer CFL may include color filters CF selectively transmitting light of different colors (or wavelength bands) therethrough. For example, the color filter layer CFL may include a first color filter CF1 positioned in the first emission area EA1 and selectively transmitting light of a first color therethrough, a second color filter CF2 positioned in the second emission area EA2 and selectively transmitting light of a second color therethrough, and a third color filter CF3 positioned in the third emission area EA3 and selectively transmitting light of a third color therethrough.

In an embodiment, at least two color filters CF which transmit different colors of light may be disposed to overlap each other in the non-emission area NEA. For example, the first color filter CF1, the second color filter CF2, and the third color filter CF3 which are stacked upon each other may be disposed in the non-emission area NEA so as to overlap the reflective layer RFL, and may overlap each other in the non-emission area NEA. Accordingly, it is possible to reduce or prevent external light reflection or the like in the non-emission area NEA without disposing a separate light blocking layer.

The overcoat layer OCL may cover the color filters CF and include at least one of an organic film and an inorganic film. For example, the overcoat layer OCL may be formed in a structure in which a first capping layer 181 including an inorganic film, a planarization layer 183 including an organic film, and a second capping layer 185 including an inorganic film are sequentially stacked. A structure and/or a material of the overcoat layer OCL are not limited and may be altered according to embodiments.

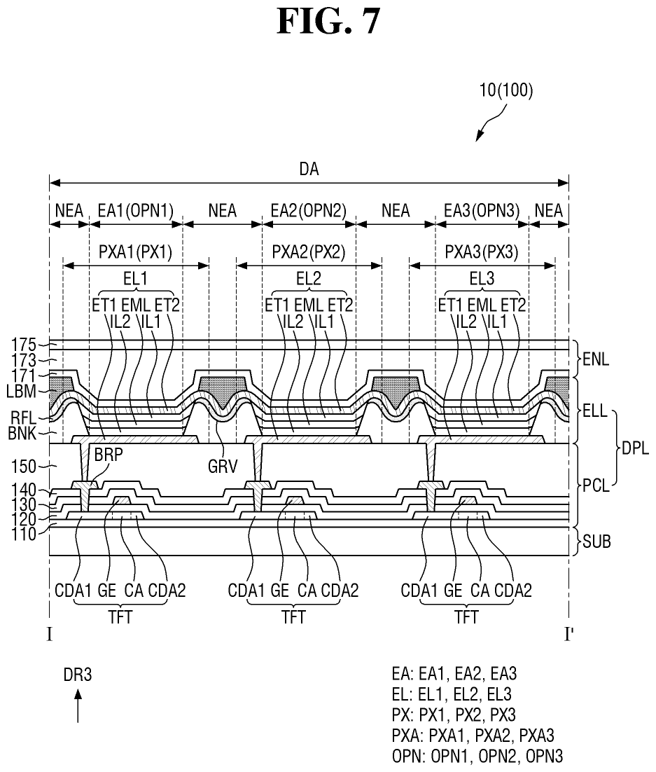

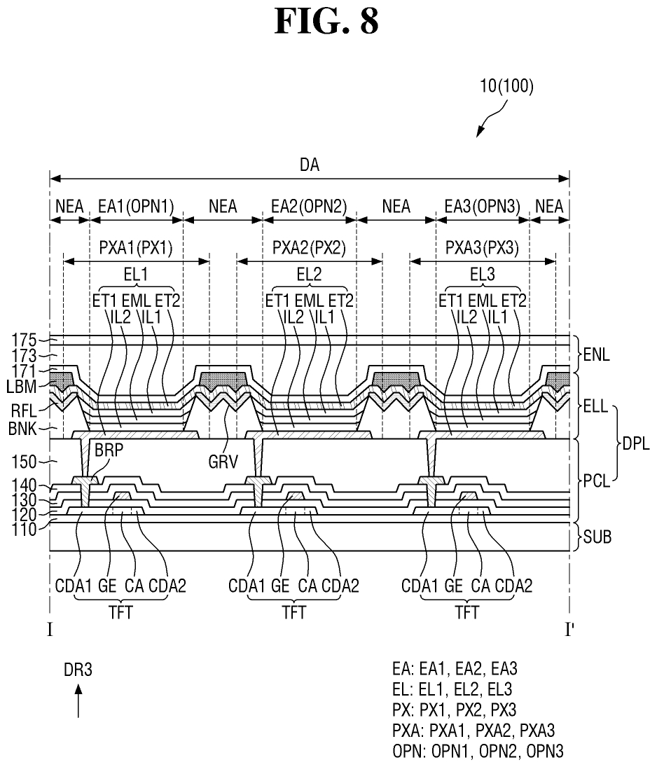

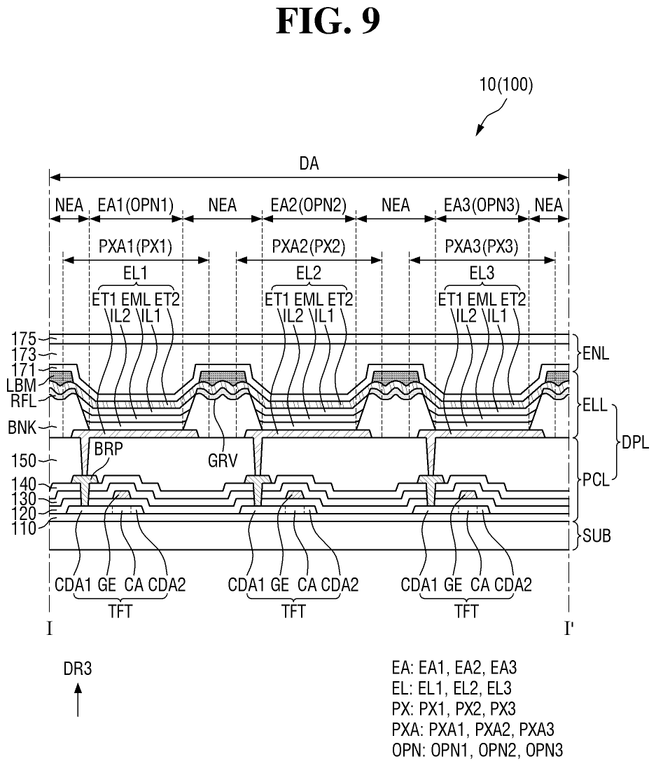

FIG. 7 is a cross-sectional view illustrating a display device 10 according to an embodiment. FIG. 8 is a cross-sectional view illustrating a display device 10 according to an embodiment. FIG. 9 is a cross-sectional view illustrating a display device 10 according to an embodiment. For example, FIGS. 7 to 9 illustrate different embodiments of a cross section of the display device 10 corresponding to line I-I′ in FIG. 2, and illustrate different modified embodiments of an embodiment of FIG. 4 in relation to the bank BNK and the reflective layer RFL as an example.

Referring to FIGS. 7 to 9 in addition to FIGS. 1 to 6, shapes of the groove GRV of the bank BNK and the reflective layer RFL may be variously changed according to respective embodiments. For example, the bank BNK may include at least one U-shaped groove GRV having a curved surface as in embodiments of FIGS. 7 and 9.

The bank BNK may include one groove GRV or at least two grooves GRV in a cross-sectional view between adjacent emission areas EA. For example, the bank BNK may include one V-shaped groove GRV as disclosed in embodiments of FIGS. 4 and 6 or include two V-shaped grooves GRV as disclosed in an embodiment of FIG. 8 between the adjacent emission areas EA. Alternatively, the bank BNK may include one U-shaped groove GRV as disclosed in an embodiment of FIG. 7 or include two U-shaped grooves GRV as disclosed in an embodiment of FIG. 9 between the adjacent emission areas EA. Alternatively, the bank BNK may include three or more grooves GRV in a cross-sectional view between the adjacent emission areas EA. In addition, shapes of the grooves GRV, sizes of the grooves GRV, the number of grooves GRV, and the like, may be variously changed according to embodiments. For example, the groove GRV may have a shape other than a V-shape and a U-shape. In addition, the bank BNK may include a plurality of grooves GRV having different shapes and/or different sizes (e.g., different widths and/or depths).

The reflective layer RFL may have a shape corresponding to the bank BNK. For example, the reflective layer RFL may have a shape corresponding to the groove GRV of the bank BNK in cross section.

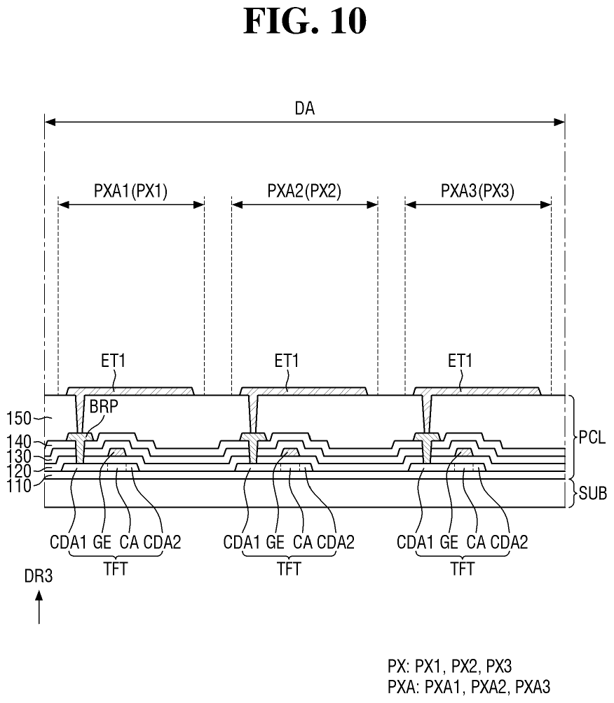

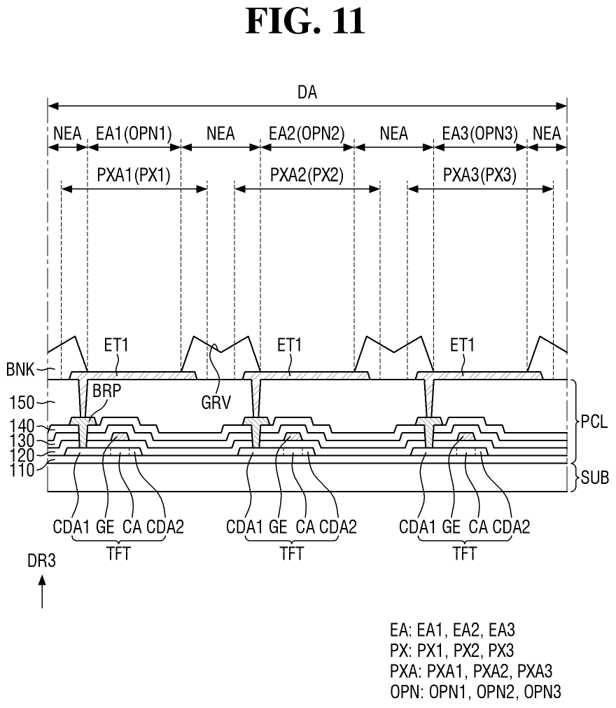

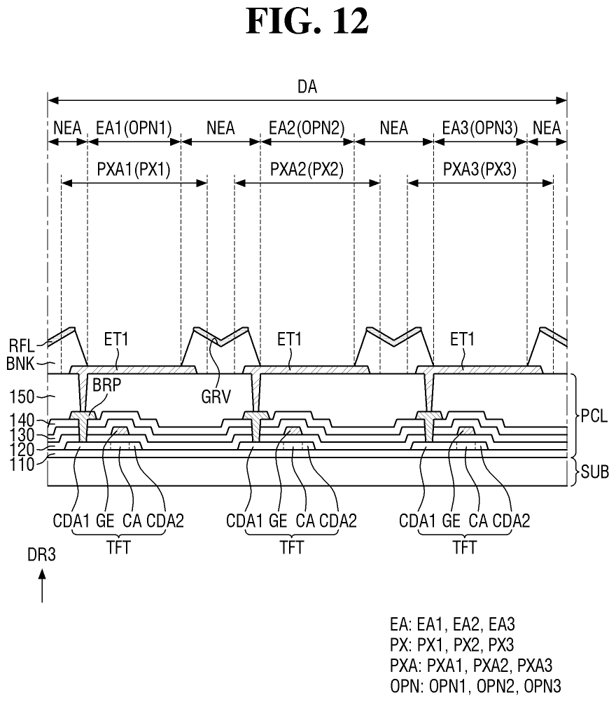

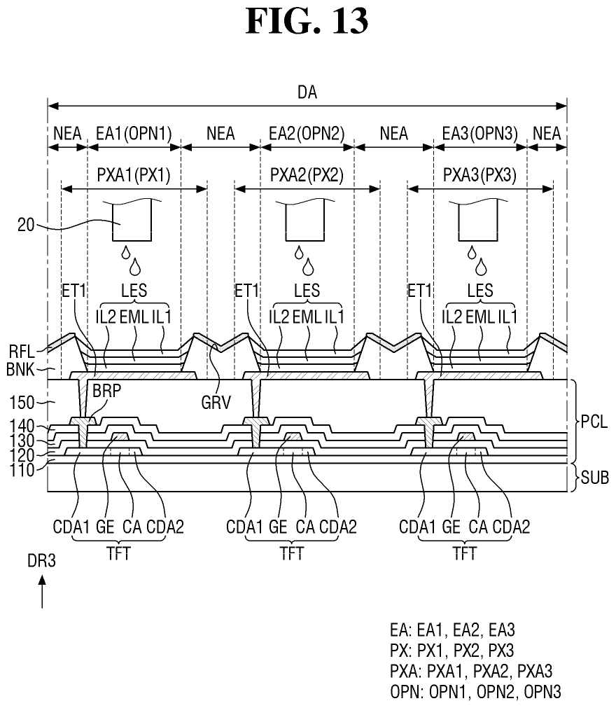

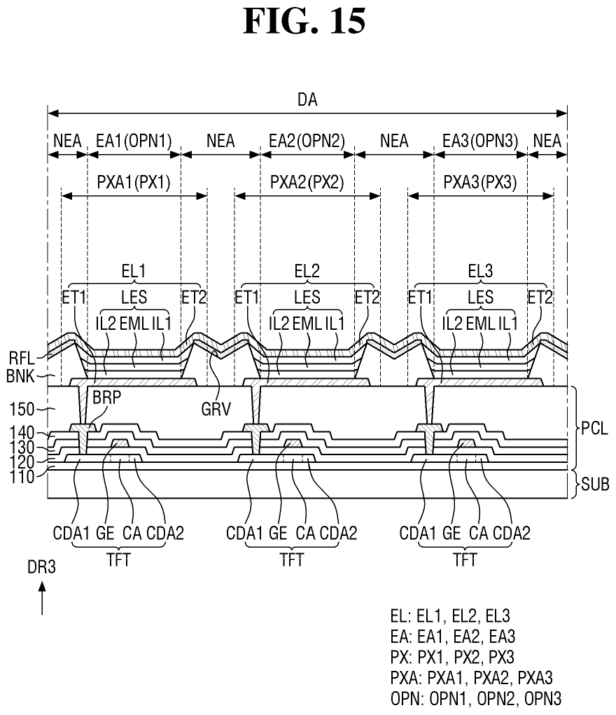

FIGS. 10 to 15 are cross-sectional views illustrating a method for manufacturing a display device 10 according to an embodiment. For example, FIGS. 10 to 15 sequentially illustrate some of manufacturing steps performed in order to manufacture the display device 10 according to an embodiment of FIG. 4.

Referring to FIGS. 1 to 10, the first electrodes ET1 may be formed on the substrate SUB. In an embodiment, the substrate SUB may include a display area DA including a plurality of pixel areas PXA (e.g., a first pixel area PXA1, a second pixel area PXA2, and a third pixel area PXA3). The panel circuit layer PCL may be first formed on the substrate SUB. Thereafter, the first electrodes ET1 may be formed in the respective pixel areas PXA on the substrate SUB on which the panel circuit layer PCL is formed. The first electrodes ET1 may be formed using the materials exemplified above, and a process method used for forming the first electrodes ET1 is not limited.

Referring to FIGS. 1 to 11, the respective emission areas EA may be defined by forming the bank BNK on the substrate SUB including the first electrodes ET1. The bank BNK may be formed using the materials exemplified above, and a process method used for forming the bank BNK is not limited. In addition, the grooves GRV may be formed in the upper surface of the bank BNK. In an embodiment, the grooves GVR may be formed by a dry etching process or the like performed after the bank BNK is primarily formed, but a method for forming the grooves GVR is not limited thereto. For example, the grooves GRV may be formed simultaneously with formation of the bank BNK using a halftone mask, a slit mask, or the like.

Referring to FIGS. 1 to 12, the reflective layer RFL may be formed on the bank BNK. For example, the reflective layer RFL may be formed on at least portions of the bank BNK including the grooves GRV. The reflective layer RFL may be formed using the materials exemplified above, and a process method used for forming the reflective layer RFL is not limited.

Referring to FIGS. 1 to 13, in each emission area EA surrounded by the bank BNK, the light emitting stack LES including the light emitting layer EML and at least one intermediate layer may be formed on the first electrode ET1. For example, in each emission area EA, the second intermediate layer IL2, the light emitting layer EML, and the first intermediate layer IL1 may be sequentially formed on the first electrode ET1. In an embodiment, the second intermediate layer IL2 may include the hole injection layer HIL and the hole transport layer HTL, and the hole injection layer HIL and the hole transport layer HTL may be sequentially formed on the first electrode ET1. In an embodiment, the first intermediate layer IL1 may include the second electron transport layer ETL2 and the first electron transport layer ETL1, and the second electron transport layer ETL2 and the first electron transport layer ETL1 may be sequentially formed on the light emitting layer EML. The respective layers included in the light emitting stack LES may be formed using the materials exemplified above.

In an embodiment, the light emitting stack LES may be formed by an inkjet printing process using an inkjet printing equipment 20. For example, at least one layer included in the light emitting stack LES (e.g., each layer included in the light emitting stack LES) may be sequentially formed by an inkjet printing process.

In an embodiment, light emitting quality may be improved by adjusting a thickness of at least one layer included in the light emitting stack LES in consideration of a resonance distance of light emitted from each light emitting layer EML. For example, thicknesses of at least one layers included the light emitting stacks LES formed in the first emission area EA1, the second emission area EA2, and the third emission area EA3 may be differentially set in consideration of an optical resonance distance corresponding to light of a first color (e.g., red light) emitted from the light emitting layer EML formed in the first emission area EA1, an optical resonance distance corresponding to light of a second color (e.g., green light) emitted from the light emitting layer EML formed in the second emission area EA2, and an optical resonance distance corresponding to light of a third color (e.g., blue light) emitted from the light emitting layer EML formed in the third emission area EA3, respectively, and accordingly, amounts of solutions supplied to the respective emission areas EA in order to form the at least one layers may be adjusted.

Referring to FIGS. 1 to 14, UV light may be irradiated from below the substrate SUB toward the reflective layer RFL using a UV exposure equipment 30 (or a UV chamber) capable of irradiating UV light (e.g., UV light of a wavelength band of approximately 365 nm). In an embodiment, a step of irradiating the UV light may be performed after a drying process, which dries the light emitting stack LES formed in the emission areas, accompanying an inkjet printing process, and may be performed in a state in which the second electrode ET2 is not formed, but is not limited thereto. For example, the step of irradiating the UV light may be performed as one of the subsequent processes performed after the formation of the reflective layer RFL and the light emitting stack LES, and may be performed after the formation of the second electrode ET2.

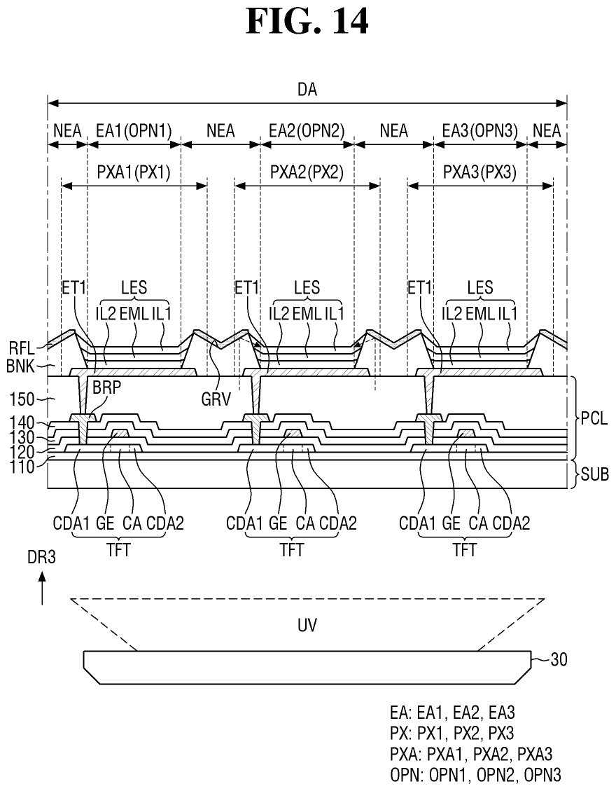

At least some of the UV light reaching the reflective layer RFL may be reflected by the reflective layer RFL and be incident on the surrounding light emitting stack LES. Some of the UV light reflected by the reflective layer RFL disposed in the non-emission area NEA adjacent to the first emission area EA1, the second emission area EA2 and the third emission area EA3 may be incident on the first intermediate layer IL1 (e.g., an edge area of the first electron transport layer ETL1 having a relatively greater thickness and/or height than the other areas) included in the light emitting stack LES in the first emission area EA1, the second emission area EA2 and the third emission area EA3, respectively. In FIG. 14, some of the UV light reflected by the reflective layer RFL disposed in the non-emission area NEA adjacent to the second emission area EA2 is illustrated as an example. According to FIG. 14, some of the UV light reflected by the reflective layer RFL disposed in the non-emission area NEA adjacent to the second emission area EA2 may be incident on the first intermediate layer IL1 (e.g., an edge area of the first electron transport layer ETL1 having a relatively greater thickness and/or height than the other areas) included in the light emitting stack LES positioned in the second emission area EA2 as indicated by dotted line arrows in FIG. 14.

Characteristics of the first intermediate layer IL1 may be adjusted or altered by the irradiation of the UV light. For example, when the first electron transport layer ETL1 of the first intermediate layer IL1 includes ZnO, defects of the first electron transport layer ETL1 may be improved as ZnO is exposed to the UV light. Accordingly, resistance of the first electron transport layer ETL1 may be decreased, and a more uniform current may flow to the light emitting element EL including the first electron transport layer ETL1. Accordingly, light emitting characteristics (e.g., luminous efficiency) of the light emitting element EL may be improved. In an embodiment, when other layers of the light emitting stack LES other than the first electron transport layer ETL1 include ZnO, defects of the layers including ZnO may be improved, such that light emitting characteristics (e.g., luminous efficiency) of the light emitting element EL may be improved.

Referring to FIGS. 1 to 15, the second electrode ET2 may be formed on the light emitting stacks LES. The second electrode ET2 may be formed using the materials exemplified above, and a process method used for forming the second electrode ET1 is not limited. As the second electrode ET2 is formed, each light emitting element EL may be formed in each emission area EA.

Thereafter, according to embodiments, the light blocking layer LBM, the encapsulation layer ENL, and the like, may be additionally formed on the substrate SUB including the light emitting elements EL. Accordingly, the display device 10 according to each embodiment may be manufactured.

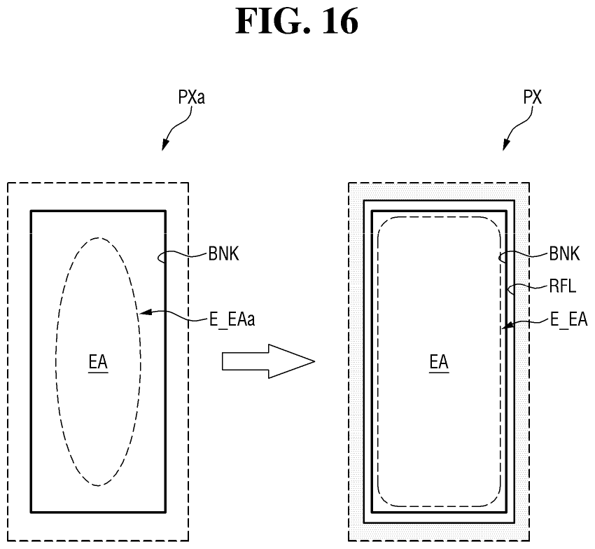

FIG. 16 is a plan view illustrating a change in light emitting characteristics of a pixel PX according to an embodiment. For example, FIG. 16 illustrates a difference between an effective emission area E_EAa of a pixel PXa that does not include the reflective layer RFL and is not manufactured through the step of irradiating the UV light described with reference to FIG. 14 and an effective emission area E_EA of a pixel PX according to an embodiment that includes the reflective layer RFL and is manufactured through the step of irradiating the UV light.

Referring to FIG. 16, the pixel PXa that does not include the reflective layer RFL and is not manufactured through the step of irradiating the UV light may exhibit relatively low luminous efficiency, and an area of the effective emission area E_EAa of the pixel PXa may be relatively small. For example, the pixel PXa may exhibit luminance less than a reference value in an edge area of the emission area EA defined by the bank BNK, and may emit light with luminance of the reference value or more only in a central portion of the emission area EA.

On the other hand, the pixel PX according to an embodiment that includes the reflective layer RFL and/or is manufactured through the step of irradiating the UV light may exhibit relatively high luminous efficiency and may exhibit luminance of the reference value or more entirely and uniformly in the emission area EA defined by the bank BNK. Accordingly, an area of the effective emission area E_EA of the pixel PX according to an embodiment may be relatively great. As an example, the effective emission area E_EA of the pixel PX according to an embodiment may be substantially similar to or identical to the emission area EA defined by the bank BNK. As such, the pixel PX according to an embodiment may exhibit more excellent light emitting characteristics (e.g., luminous efficiency and/or light emitting quality).

As described above, the display device 10 according to embodiments may include the bank BNK surrounding the emission areas EA of the pixels PX and including the grooves GRV positioned in the upper surface thereof and the reflective layer RFL disposed on the grooves GRV of the bank BNK. Light loss of the pixels PX is reduced or minimized by the reflective layer RFL, such that luminous efficiency of the pixels PX and the display device 10 including the pixels PX may be increased.

A method for manufacturing a display device 10 according to embodiments may include partitioning the emission area EA by forming the bank BNK on the substrate SUB on which the first electrode ET1 or the like is formed and forming the groove GRV in the upper surface of the bank BNK, forming the reflective layer RFL on at least a portion of the bank BNK including the groove GRV, forming the light emitting stack LES on the first electrode ET1 in the emission area EA surrounded by the bank BNK, the light emitting stack LES including the light emitting layer EML and at least one intermediate layer, and irradiating the UV light from below the substrate SUB to the reflective layer RFL. At least some of the UV light irradiated to the reflective layer RFL may be reflected by the reflective layer RFL and be incident on the light emitting stack LES, and may change characteristics of the light emitting stack LES. For example, defects of at least one intermediate layer (e.g., the first electron transport layer HTL1) included in the light emitting stack LES may be improved and resistance of the at least one intermediate layer may be decreased by the UV light. Accordingly, luminous efficiency of the light emitting element EL and the pixel PX including the light emitting element EL may be increased, and light emitting quality of the light emitting element EL and the pixel PX including the light emitting element EL may be improved.

According to the above-described embodiments, the display device 10 with improved luminous efficiency and the method for manufacturing the same may be provided.

In concluding the detailed description, those skilled in the art will appreciate that many variations and modifications can be made to the preferred embodiments without substantially departing from the principles of the present inventive concept. Therefore, the disclosed preferred embodiments of the inventive concept are used in a generic and descriptive sense only and not for purposes of limitation.

What is claimed is:

1. A display device comprising:
a first electrode disposed in an emission area;
a bank disposed around the emission area to surround the emission area and including a groove formed in an upper surface thereof;
a light emitting stack disposed on the first electrode surrounded by the bank and including a light emitting layer and a first intermediate layer overlapping the light emitting layer;
a second electrode disposed on the light emitting stack; and
a reflective layer disposed on at least a portion of the bank to cover the groove.

2. The display device of claim 1, wherein the first intermediate layer includes a first electron transport layer having a greater thickness or height in an edge area adjacent to the bank than in the other areas.

3. The display device of claim 2, wherein the first electron transport layer includes ZnO.

4. The display device of claim 2, wherein the first intermediate layer further includes a second electron transport layer disposed between the light emitting layer and the first electron transport layer.

5. The display device of claim 1, wherein the first intermediate layer is disposed between the light emitting layer and the second electrode, and
wherein the light emitting stack further includes a second intermediate layer disposed between the first electrode and the light emitting layer.

6. The display device of claim 1, wherein the reflective layer completely surrounds the emission area in a plan view.

7. The display device of claim 1, wherein the display device includes emission areas which include the emission area and are spaced apart from each other, and
wherein the bank is disposed between adjacent emission areas to surround each of the emission areas, and includes at least one V-shaped or U-shaped groove disposed between the adjacent emission areas.

8. The display device of claim 7, wherein the reflective layer has a curved surface or an inclined surface corresponding to the groove of the bank.

9. The display device of claim 7, wherein the reflective layer includes a mesh-shaped pattern layer including openings corresponding to the emission areas and surrounds each of the emission areas.

10. The display device of claim 7, wherein the reflective layer includes reflective patterns which are separated from each other and surround the emission areas, respectively.

11. The display device of claim 1, wherein the first electrode includes a reflective electrode layer,
the second electrode includes a transparent electrode layer, and
light emitted from the light emitting layer is transmitted through the second electrode and is emitted in an upward direction of the light emitting layer.

12. The display device of claim 1, further comprising a light blocking layer or at least two color filters disposed on the reflective layer to overlap the reflective layer.

13. A display device comprising:
a first electrode disposed in an emission area and including a reflective electrode layer;
a bank disposed around the emission area to surround the emission area and including a groove formed in an upper surface thereof;
a light emitting stack disposed on the first electrode, surrounded by the bank, including a light emitting layer and at least one intermediate layer overlapping the light emitting layer;
a second electrode disposed on the light emitting stack and including a transparent electrode layer; and
a reflective layer disposed on at least a portion of the bank to cover the groove.

14. The display device of claim 13, wherein the light emitting layer is a quantum dot light emitting layer including quantum dots.

15. The display device of claim 13, wherein the at least one intermediate layer includes an electron transport layer including ZnO.

16. The display device of claim 15, wherein the electron transport layer has a greater thickness or height in an area adjacent to the bank than in the other areas.

17. The display device of claim 13, wherein the groove of the bank completely surrounds the emission area in a plan view, and includes at least one V-shaped or U-shaped groove in cross section.

18. The display device of claim 17, wherein the reflective layer completely surrounds the emission area in a plan view and has a curved surface or an inclined surface corresponding to the groove of the bank.

19. A method for manufacturing a display device, comprising:
forming a first electrode on a substrate;
forming a bank on the first electrode to surround the first electrode to define an emission area, the bank including a groove in an upper surface;
forming a reflective layer on at least a portion of the bank to cover the groove;
forming a light emitting stack on the first electrode in the emission area surrounded by the bank, the light emitting stack including a light emitting layer and at least one intermediate layer;
irradiating ultraviolet (UV) light from below the substrate toward the reflective layer; and
forming a second electrode on the light emitting stack.

20. The method for manufacturing a display device of claim 19, wherein the light emitting stack is formed by an inkjet printing process.
